(19) United States
(12) Patent Application Publication
(10) Pub. No.: US 2018/0027702 A1
(43) Pub. Date: Jan. 25, 2018

(54) FLUID MANIFOLD

(71) Applicant: Hewlett Packard Enterprise Development LP, Houston, TX (US)

(72) Inventors: Tahir Cader, Liberty Lake, WA (US); John P. Franz, Houston, TX (US)

(21) Appl. No.: 15/547,534

(22) PCT Filed: Feb. 17, 2015
(86) PCT No.: PCT/US15/16141

§ 371 Date: Jul. 31, 2017

(51) Int. Cl. H05K 7/20

(52) U.S. Cl. CPC H05K 7/20772

(57) ABSTRACT

An example fluid manifold is provided herein. The fluid manifold includes a first set of perimeter walls, a second set of perimeter walls, a first aperture, and a second aperture. The first set of perimeter walls to form a supply channel. The second set of perimeter walls to form a return channel. The second set of perimeter walls are adjacent to the first set of perimeter walls. The first aperture formed in the first set of perimeter walls is to transport fluid between a fluid component and the supply channel. The second aperture formed in the second set of perimeter walls is to transport fluid between the fluid component and the return channel. The first aperture and the second aperture are positioned adjacent to an electronic module.

### BACKGROUND

Electronic devices have temperature requirements. Heat from the use of the electronic devices is controlled using cooling systems. Examples of cooling systems include air and liquid cooling.

### BRIEF DESCRIPTION OF THE DRAWINGS

Non-limiting examples of the present disclosure are described in the following description, read with reference to the figures attached hereto and do not limit the scope of the claims. In the figures, identical and similar structures, elements or parts thereof that appear in more than one figure are generally labeled with the same or similar references in the figures in which they appear. Dimensions of components and features illustrated in the figures are chosen primarily for convenience and clarity of presentation and are not necessarily to scale. Referring to the attached figures:

FIG. 1 illustrates a block diagram of a system to regulate a temperature of an electronic module according to an example;

FIG. 2 illustrates an exploded view of the system of FIG. 1 according to an example;

FIGS. 3-6 illustrate schematic diagrams of the system of FIG. 1 according to an example;

FIG. 7 illustrates a block diagram of an apparatus to regulate a temperature of an electronic module according to an example;

FIG. 8 illustrates an exploded view of the apparatus of FIG. 7 according to an example;

FIG. 9 illustrates a block diagram of a fluid manifold according to an example;

FIG. 10 illustrates a perspective view of the fluid manifold of FIG. 9 according to an example; and

FIG. 11 illustrates a cross-sectional view of the fluid manifold of FIG. 9 according to an example.

### DETAILED DESCRIPTION

In the following detailed description, reference is made to the accompanying drawings which form a part hereof, and in which is depicted by way of illustration specific examples in which the present disclosure may be practiced. It is to be understood that other examples may be utilized and structural or logical changes may be made without departing from the scope of the present disclosure.

Electronic system designs balance conflicts between power density, spatial layout, temperature requirements, acoustic noise, and other factors on the electronic devices. Liquid cooling can be more efficient than air cooling; however, as the liquid goes through the plumbing connections the risk of leakage of liquid within the electronic device is introduced. Limiting the amount of fluid connections and fluid tubing on the electronic device can reduce the risk of leaking.

In examples, a fluid manifold is provided. The fluid manifold includes a first set of perimeter walls, a second set of perimeter walls, a first aperture, and a second aperture. The first set of perimeter walls to form a supply channel. The second set of perimeter walls to form a return channel. The second set of perimeter walls are adjacent to the first set of perimeter walls. The first aperture formed in the first set of perimeter walls is to transport fluid between a fluid component and the supply channel. The second aperture formed in the second set of perimeter walls is to transport fluid between the fluid component and the return channel. The first aperture and the second aperture are positioned adjacent to an electronic module. The electronic module includes the fluid component thereon.

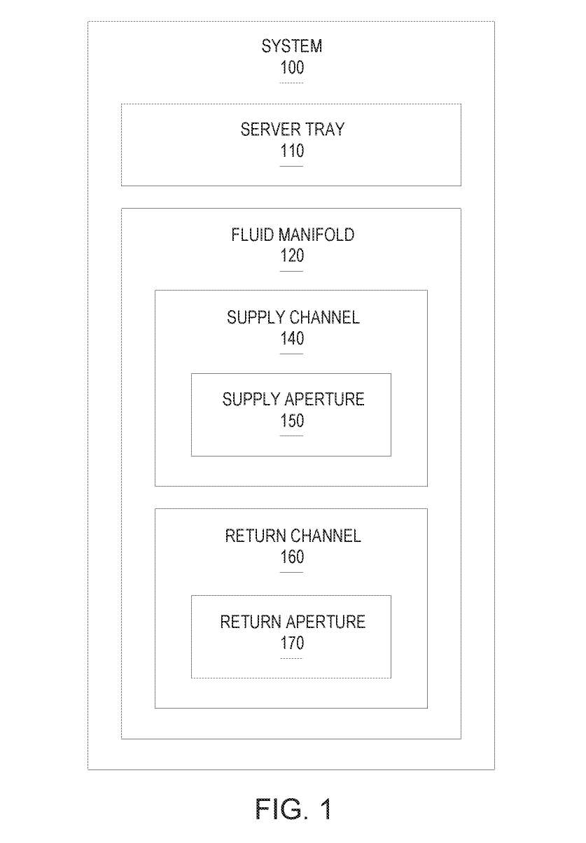

FIG. 1 illustrates a block diagram of a system 100 to regulate a temperature of an electronic module according to an example. The system 100 includes a server tray 110 and a fluid manifold 120. The server tray 110 is to receive the electronic module. The fluid manifold 120 is to connect to the server tray 110. The fluid manifold 120 includes a supply channel 140 and a return channel 160. The supply channel 140 is to transport a liquid to a supply aperture 150 positioned along the supply channel 140. The supply aperture 150 is connected to a fluid component to provide the liquid thereto. The return channel 160 to transport a liquid from a return aperture 170 positioned along the return channel 160. The return aperture 170 is connected to the fluid component to receive the liquid therefrom.

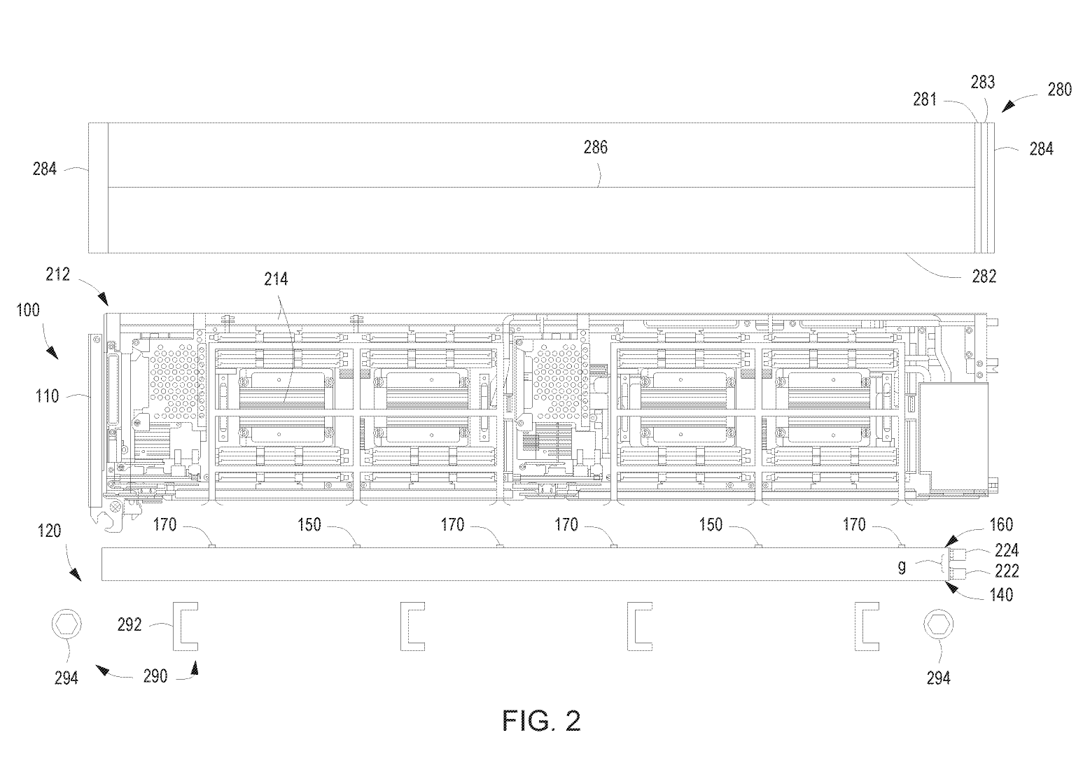

FIG. 2 illustrates an exploded view of the system 100 of FIG. 1 according to an example. The system 100 includes the server tray 110, the fluid manifold 120, a support member 280, and a retaining member 290. The server tray 110 receives the electronic module 212 and a set of fluid components 214 that are attached to the electronic module 212. For example, the set of fluid components 214 may include a liquid cooled cold plate attached to a printed circuit board, hard drive, memory, graphical processing units (GPUs), voltage regulators, and/or power supplies.

The support member 280 is to receive the server tray 110 with the electronic module 212, and the fluid manifold 120. The support member 280 includes a base 282, a pair of side walls 284 extending from the base 282, and a shelf 286 to receive the server tray 110. The support member 280 may be formed to receive the fluid manifold 120. The fluid manifold 120 may be secured to the server tray 110 using a retaining member 290. For example the retaining member 290 may include a retaining bracket 292 and/or a fastener 294. Other retaining members may include, for example, clips, screws, clamps, and/or bolts.

The fluid manifold 120 includes the supply channel 140 with a supply aperture 150 and the return channel 160 with a return aperture 170. The supply channel 140 and the return channel 160 are separate chambers that may be spaced apart from one another to reduce the transfer of heat therebetween. For example, the supply channel 140 and the return channel 160 may be separated by a gap, g. The supply apertures 150 and the return apertures 170 are aligned adjacent to the electronic module 212 on the server tray or attached thereto; however, the fluid manifold 120 is not part of the electronic module. The supply aperture 150 and the return aperture 170 are each aligned with the fluid component 214 that is on the electronic module 212. In order to align the supply aperture 150 and the return aperture 170, the apertures are adjustable to provide customization based on the specific system 100 requirements. For example, variations in the electronic module 212 and the fluid components 214 may use the same fluid manifold 120, with the supply aperture 150 and the return aperture 170 customized to adapt or fit on the specific configuration. For example, the supply aperture 150 and the return aperture 170 may receive connectors and/or plugs. The use of connectors and plugs interchangeably in the supply aperture 150 and return aperture 170 provides an adaptable configuration that may be customized to accommodate the fluid components 214 on the electronic module 212.

The adaptability of the supply aperture 150 and return aperture 170 provides for easily changing the configuration of the fluid manifold 120 based on the electronic module 212 and the fluid components 214. Customization of the fluid manifold 120 avoids the need to make changes to the fluid components 214 on the electronic module 212, which not only saves time and money, but may also reduce leaks by accommodating existing fluid connections. For instance, the fluid components 214 may include fluid tubing that runs within the electronic module. The ability to customize the configuration of the fluid manifold 120 to accommodate the fluid tubing on the electronic module 212 provides an opportunity to optimize the fluid paths based on a particular need of each system without worrying about fixed connections on the fluid manifold 120. The customization of the fluid manifold 120 also enables customized configurations of the electronic module 212 that may be changed by making small adjustments to the fluid manifold 120.

The system 100 may further include a supply valve 222 to provide fluid to the supply channel 140 for the supply aperture 150 and a return valve 224 to remove the fluid the return channel 160 receives from the return aperture 170. The supply valve 222 may receive fluid from a fluid supply line 281 and the return valve 224 may provide the fluid removed to a fluid return line 283. The support member 280 may include fluid supply and return lines 281, 283 and position the fluid supply line 281 to mate with the supply valve 222 and a fluid return line 283 to mate with a return valve 224.

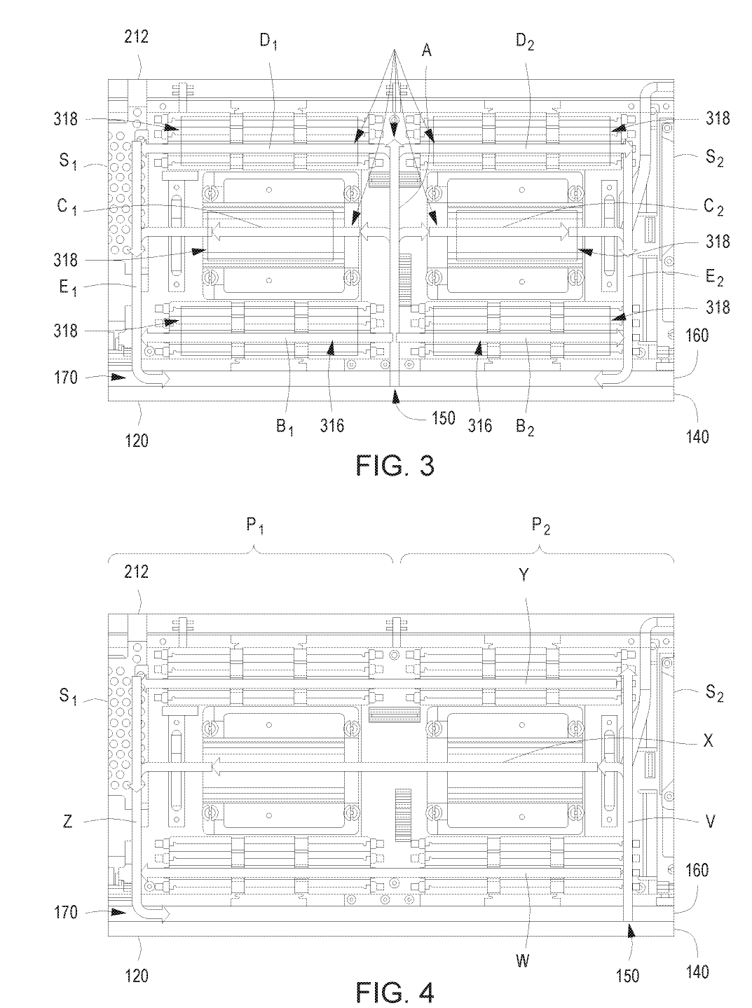

FIGS. 3-6 illustrate schematic diagrams of the system 100 of FIG. 1 according to an example. FIGS. 3-6 illustrate the fluid manifold 120 and the electronic module 212. The fluid manifold 120 supplies via the supply channel 140 and the supply aperture 150 the set of fluid tubes with fluid, such as water. The fluid may be supplied to the fluid manifold 120 via the fluid supply valve 222, illustrated in FIG. 2. The fluid is distributed across the fluid components 214 on the electronic module 212 to remove heat therefrom. For example, the fluid components 214 may include a set of fluid tubes 316 that connect the supply and return aperture 150, 170 and a thermal plate 318 on the electronic module 212, such as a printed circuit board, hard drive, memory, dual in-line memory modules (DIMMS), graphical processing units (GPUs), voltage regulators, and/or power supplies.

The fluid tubes 316 are illustrated in various configurations. Referring to FIG. 3, the fluid moves across the electronic module 212 starting in the center at tube A. From tube A, the fluid is distributed across both sides, in parallel, through tubes B1, B2, C1, C2, D1, and D2 towards opposite sides S1, S2 of the electronic module 212 and towards the tubes E1 and E2. The tubes B1-D2 are parallel to one another and perpendicular to tube A. The fluid manifold 120 then receives the fluid from tubes E1 and E2 on opposite sides S1, S2 of the electronic module 212 via the return aperture 170 of the return channel 160.

In contrast, FIG. 4 illustrates the fluid moving across the electronic module 212 starting at tube V, which is on one side S2 of the electronic module 212. The fluid moves from tube V to tubes W, X, and Y in parallel and are illustrated in a position parallel to one another and extending from the tube V. Tubes W, X, and Y carry the fluid in series from electronic components P2 to electronic components P1 towards the other side S1 of the electronic module 212 to tube Z. Tube Z transports the fluid out of the electronic module 212 and to the fluid manifold 120 via the return aperture 170 and the return channel 160. Once in the fluid manifold 120, the fluid may be removed via the fluid return valve 224, illustrated in FIG. 2. The serial paths of the fluid tubes reduces the number of fluid tube connections within the electronic module 212, which also reduces the number of locations that the connections can leak. Serial flow paths may also be used to provide warmer water output from the fluid tubes in the electronic module 212, via the return aperture 170 which connects to the return channel 160. Additionally, serial flow paths may be used to obtain central processing unit (CPU) pump redundancy if such a cooling system is used.

FIGS. 3-4 illustrate examples of serial and parallel fluid flow paths. Other flow path may also be utilized with the system 100. FIGS. 5-6 illustrate two additional examples. Referring to FIG. 5, a variation of a parallel fluid flow path of FIG. 3 is illustrated. In FIG. 5, the supply and return apertures 150, 170 are positioned adjacent to one another in the center of the electronic module 212 between the two sides S1, S2. Positioning the supply and return apertures 150, 170 adjacent to one another enables use of a smaller fluid manifold 120 and/or a larger electronic module 212. The fluid may enter the electronic module 212 through tube A and exit the electronic module through tube E. The use of parallel paths through tubes B1, B2, C1, C2, D1, D2 enhance the cooling and provides for lower pressure drops due to the use of shorter fluid tubes 316, illustrated as tubes B1, B2, C1, C2, D1, D2, F1, F2, F3, F4, distributed across the electronic module 212.

Referring to FIG. 6, the flow path illustrated a variation of a serial fluid flow path of FIG. 4 is illustrated. Tube V supplies the fluid to tube X, which transports the fluid across a portion of the electronic module 212. The fluid is then routed to tubes T1 and T2, which then transport the fluid across other portions of the electronic module 212 via tubes W and Y. The fluid may then be transported to tube Z which removes the fluid from the electronic module 212. In FIG. 6, the supply and return apertures 150, 170 are positioned adjacent to one another to enable the fluid to be provided to and received from the electronic module 212 via tubes V and Z on the same side, i.e. S2 of the electronic module 212. Positioning the supply and return apertures 150, 170 in close proximity to one another enables use of a smaller fluid manifold 120 and/or a larger electronic module 212.

The fluid paths illustrated in FIGS. 3-6 distribute fluid across the electronic module 212 to maintain or regulate the temperature of the electronic module 212 and the components therein. For example, the temperature may need to be regulated based on temperature and/or the environment surrounding the system 100, such as a data center or performance optimized data center (POD) housing the electronic module 212. In a POD environment, depending on the location and temperature the fluid may warm up the system 100 components prior to use, warm up the system 100 components during use, cool down the system prior to use, or cool down the system 100 during use. Additionally, the fluid may be used to maintain proper or optimal temperature of the electronic module 212 and system 100 during normal or heavy workloads.

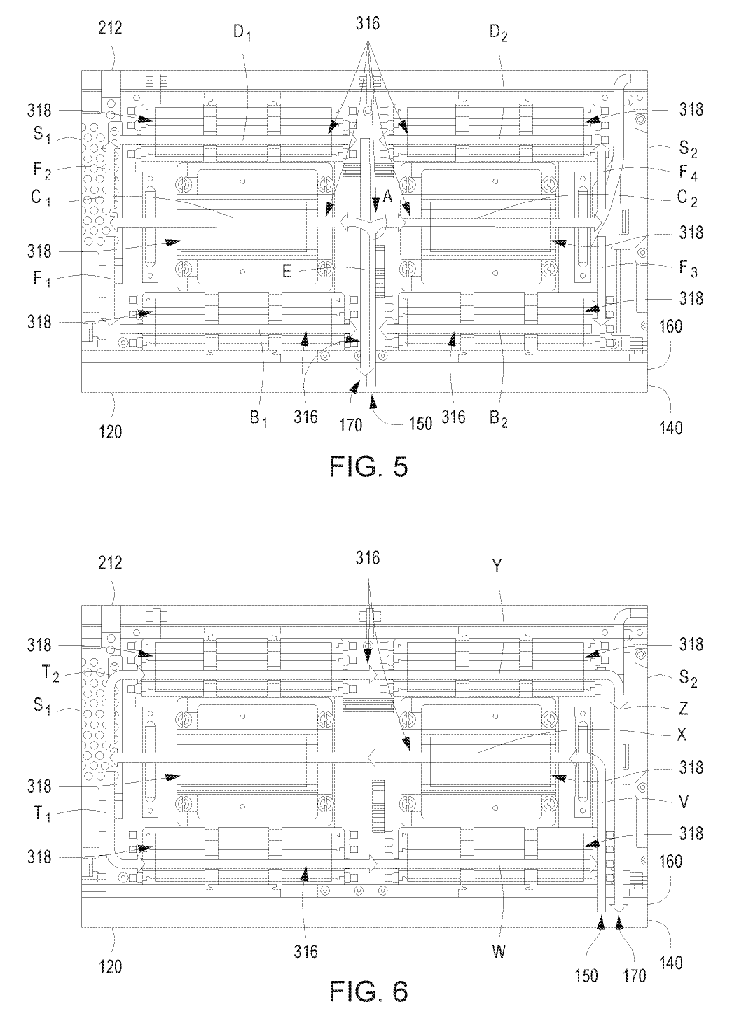

FIG. 7 illustrates a block diagram of an apparatus to regulate the temperature of an electronic module 212 according to an example. Examples of the electronic module 212 referred to herein are illustrated in FIGS. 2-4 and 6. The apparatus 700 includes a fluid manifold 120, a supply connector 780, and a return connector 790. The fluid manifold 120 includes a supply channel 140 and a return channel 160. The supply channel 140 includes a supply aperture 150 formed therein to connect to a fluid component 214 in the electronic module 212 and provide the fluid thereto. The return channel 160 includes a return aperture 170 formed therein to connect to a fluid component 214 and receive the fluid therefrom. The supply connector 780 is connected to the supply aperture 150 to provide the liquid to the fluid component 214. The return connector 790 is connected to the return aperture 170 to receive a liquid from the fluid component 214.

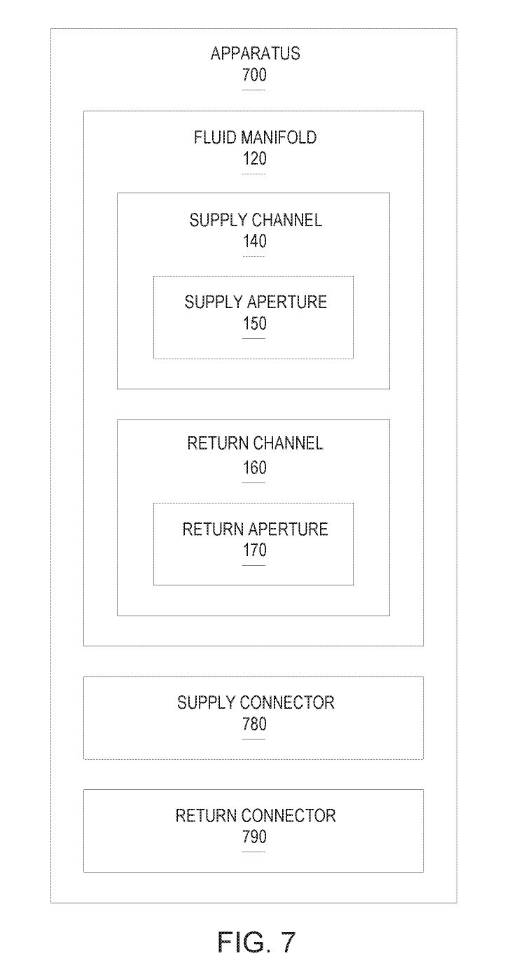

FIG. 8 illustrates an exploded view of the apparatus 700 of FIG. 7 according to an example. FIG. 8 illustrates the apparatus 700 with the electronic module 212 adjacent thereto. As illustrated, the supply connector 780 is connected to the supply aperture 150. The supply connector 780 aligns with the fluid component 214 on the electronic module 212 at a customized position, such that the customized position of the supply connector 780 is adjacent to the fluid component 214 on the electronic module 212. Similarly, the return connector 790 is connected to the return aperture 170. The return connector 790 aligns with the fluid component 214 at a customized position, such that the customized position of the return connector 790 is adjacent to the fluid component 214 on the electronic module 212.

Additional supply and return apertures 150, 170 may be available that receive a connector, i.e., a supply or return connector 780, 790, when in use or receive a plug when apertures are not in use. For example a supply plug 880 and a return plug 890 may be used to plug or cover the supply and/or return apertures 150,170 not in use. An ability to use interchangeable plugs and connectors provides for customization of the fluid manifold 120. Moreover, the presence of additional supply and return apertures 150, 170 that are not used for fluid connections provides an opportunity to use the apertures for monitoring the apparatus 700 and/or fluid flowing therethrough. For example, the plugs 880, 890 may include sensors 885 to obtain, for example, temperature, pressure, and/or flow data. The sensors 885 may be connected to the system 100 and may be integrated into other modules, such as a monitor module 895 that monitors the system 100.

The supply connector 780 and the return connector 790 may be connected to fluid tubes 316 on the electronic module 212. The fluid tubes 316 carry the fluid through the electronic module 212. The fluid tubes 316 may also carry the fluid to and from thermal plates 318. The thermal plates 318 are thermally conductive and may be placed adjacent to the electronic components in the electronic module 212 to receive and transfer heat between the electronic components and the fluid. For example, the thermal plates 318 to receive and transfer heat from electronic components to the fluid when cool fluid is used to cool down the electronic module 212. In contrast, the thermal plates 318 may also receive and transfer heat from heated fluid to electronic components when heated fluid is used to warm up the electronic module 212

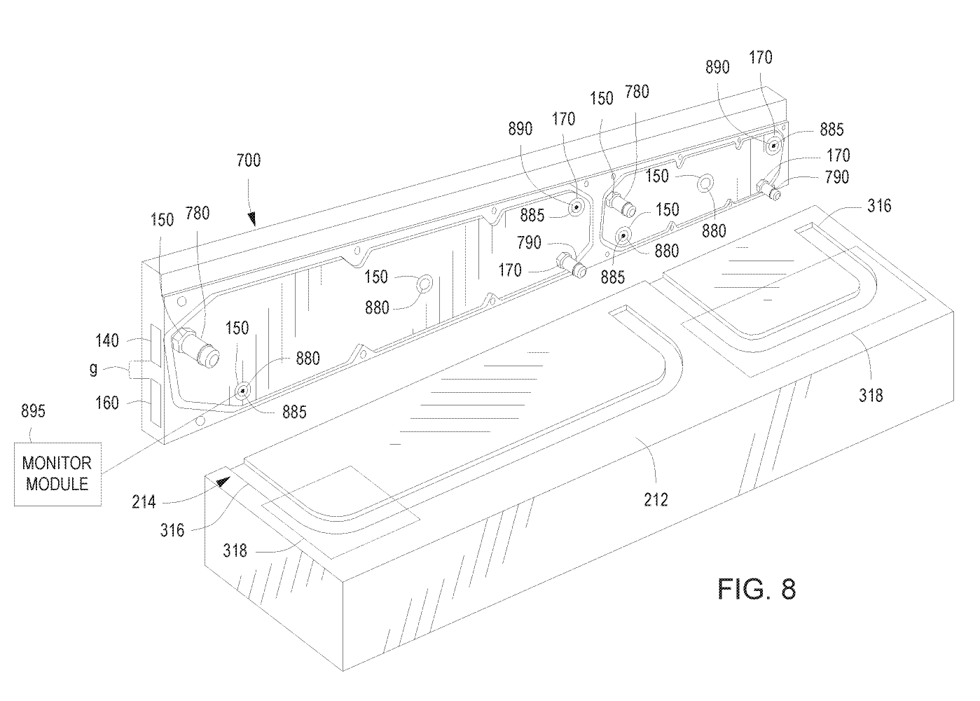

FIG. 9 illustrates a block diagram of a fluid manifold 120 according to an example. The fluid manifold 120 includes a first set of perimeter walls 940, a second set of perimeter walls 960, a first aperture 950, and a second aperture 960. The first set of perimeter walls 940 is to form a supply channel 140. The second set of perimeter walls 960 is to form a return channel 160. The second set of perimeter walls 960 is adjacent to the first set of perimeter walls 940.

The first aperture 950 is formed in the first set of perimeter walls 940 to transport a fluid between a fluid component 214 and the supply channel 140. The second aperture 970 formed in the second set of perimeter walls 960 to transport the fluid between the fluid component 214 and the return channel 160. The first aperture 950 and the second aperture 970 are positioned adjacent to an electronic module 212 that includes the fluid component 214 thereon.

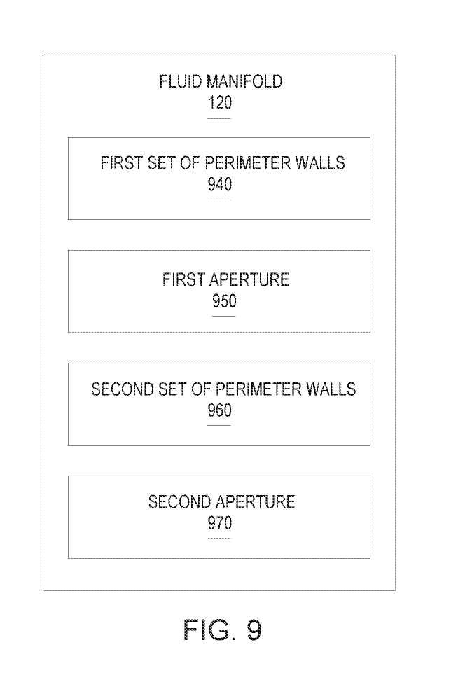

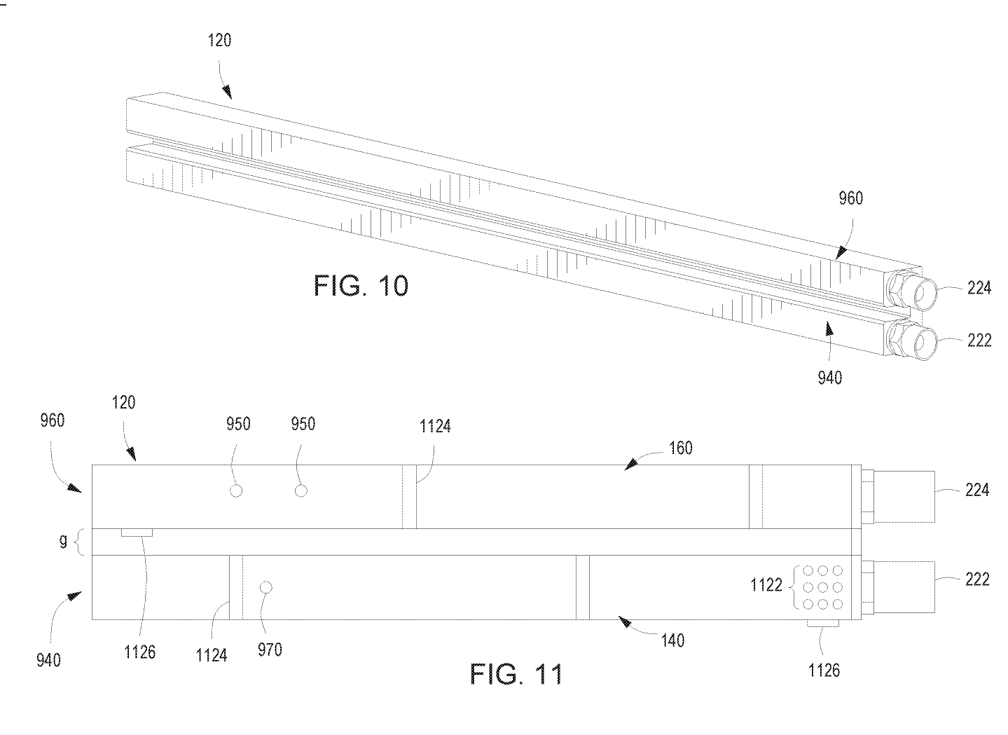

FIG. 10 illustrates a perspective view of the fluid manifold 120 of FIG. 9 according to an example. FIG. 11 illustrates a cross-sectional view of the fluid manifold 120 of FIG. 9 according to an example. Referring to FIG. 10, the fluid manifold 120 includes the first set of perimeter walls 940 and the second set of perimeter walls 960. The first set of perimeter walls 940 may form a fluid-tight seal between the perimeter walls to prevent a fluid from leaking from the perimeter walls when the fluid is transported thereacross via the supply channel 140. The second set of perimeter walls 960 may form a fluid-tight seal between the perimeter walls to prevent a fluid from leaking from the perimeter walls when the fluid is transported thereacross via the return channel 160. The first set of perimeter walls 940 and the second set of perimeter walls 960 are spaced apart from one another, which is illustrated as a gap, g, between the two sets of perimeter walls. In other words, each of the perimeter walls are distinct walls and with no overlap of the walls between the first set of perimeter walls 940 and the second set of perimeter walls 960.

Referring to FIGS. 10-11, the first and second set of perimeter walls 940, 960 are adaptable to receive the first aperture 950 and the second aperture 970 at a plurality of positions to customize the fluid manifold 120. For example, within the first and second set of perimeter walls 940, 960, the supply channel 140 and the return channel 160 are formed. The position of the first aperture 950 or supply aperture 150 within the supply channel 140 and position of the second aperture 970 or return aperture 170 within the return channel may be adjusted to accommodate the fluid component 214, such that the fluid manifold 120 may be customizable based on a configuration or type of the fluid component 214 on the electronic module 212.

The fluid manifold 120 receives the fluid from one valve, such as a supply valve 832, and removes the fluid from another valve, such as a return valve 834. The fluid manifold 120 may further include flow and pressure controls to control the flow of the fluid based on water temperature and/or server load. The controls may be attached to a part of the supply and return valves 832, 834 or it may be integrated into the fluid manifold. For example, the supply channel 140 and the return channel 160 may each include a set of flow controls consisting of round protrusions or bumps that are clustered 1122 along the supply channel 140 and/or the return channel 160, and/or rounded bumps that span across 1124 a portion of the supply channel 140 and/or the return channel 160 to control the flow of the fluid and slow down the flow. Moreover, the supply channel 140 and the return channel 160 further include an overflow member 1126 to receive excess fluid or release fluid when pressure builds up in the supply channel 140 and/or the return channel 160.

The present disclosure has been described using non-limiting detailed descriptions of examples thereof and is not intended to limit the scope of the present disclosure. It should be understood that features and/or operations described with respect to one example may be used with other examples and that not all examples of the present disclosure have all of the features and/or operations illustrated in a particular figure or described with respect to one of the examples. Variations of examples described will occur to persons of the art. Furthermore, the terms “comprise,” “include,” “have” and their conjugates, shall mean, when used in the present disclosure and/or claims, “including but not necessarily limited to.”

It is noted that some of the above described examples may include structure, acts or details of structures and acts that may not be essential to the present disclosure and are intended to be exemplary. Structure and acts described herein are replaceable by equivalents, which perform the same function, even if the structure or acts are different, as known in the art. Therefore, the scope of the present disclosure is limited only by the elements and limitations as used in the claims.

What is claimed is:

1. A system to regulate a temperature of an electronic module, the system comprising:
a server tray to receive the electronic module;
a fluid manifold to connect to the server tray, the fluid manifold including:
a supply channel to transport a liquid to a supply aperture positioned along the supply channel, the supply aperture connected to a fluid component to provide the liquid thereto, and
a return channel to transport a liquid from a return aperture positioned along the return channel, the return aperture connected to the fluid component to receive the liquid therefrom.

2. The system of claim 1, wherein the supply aperture and the return aperture each align with the fluid component.

3. The system of claim 1, wherein the fluid component is attached to the electronic module.

4. The system of claim 1, wherein the supply aperture and the return aperture are positioned on the server tray adjacent to the electronic module.

5. The system of claim 1, further comprising a supply valve and a return valve.

6. An apparatus to regulate a temperature of an electronic module, the apparatus comprising:
a fluid manifold including:
a supply channel with a supply aperture formed therein to connect to a fluid component in the electronic module and provide fluid thereto, and
a return channel with a return aperture formed therein to connect to the fluid component and receive fluid therefrom;
a supply connector connected to the supply aperture to provide a liquid to the fluid component; and
a return connector connected to the return aperture to receive a liquid from the fluid component.

7. The apparatus of claim 6, wherein the supply connector aligns with the fluid component at a customized position adjacent to the electronic module.

8. The apparatus of claim 6, wherein the return connector aligns with the fluid component at a customized position adjacent to the electronic module.

9. A fluid manifold comprising:
a first set of perimeter walls to form a supply channel;
a second set of perimeter walls to form a return channel, the second set of perimeter walls adjacent to the first set of perimeter walls;
a first aperture formed in the first set of perimeter walls to transport fluid between a fluid component and the supply channel; and
a second aperture formed in the second set of perimeter walls to transport fluid between the fluid component and the return channel,
wherein the first aperture and the second aperture are positioned adjacent to an electronic module, the electronic module including the fluid component thereon.

10. The fluid manifold of claim 9, wherein the first set of perimeter walls form a fluid-tight seal therebetween to prevent fluid from leaking therefrom when fluid is transported thereacross.

11. The fluid manifold of claim 9, wherein the second set of perimeter walls form a fluid-tight seal therebetween to prevent fluid from leaking therefrom when fluid is transported thereacross.

12. The fluid manifold of claim 9, wherein the first set of perimeter walls and the second set of perimeter walls are spaced apart from one another.

13. The fluid manifold of claim 9, wherein the positions of the first aperture and the second aperture are adjustable to accommodate the fluid component.

14. The fluid manifold of claim 9, wherein the first set of perimeter walls and the second set of perimeter walls are adaptable to receive the first aperture and the second aperture at a plurality of positions.

15. The fluid manifold of claim 9, wherein the supply channel and the return channel further comprise an overflow member to receive excess fluid.
